(19) United States
(12) Patent Application Publication
(10) Pub. No.: US 2007/0080346 A1
(43) Pub. Date: Apr. 12, 2007

(54) Organic thin film transistor array panel

(75) Inventors: Bo-Sung Kim, Seoul (KR); Kyu-Sik Kim, Suwon-si (KR); Jung-Han Shin, Suwon-si (KR); Mun-Pyo Hong, Seongnam-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/543,770

(22) Filed: Oct. 4, 2006

(30) Foreign Application Priority Data
Oct. 7, 2005 (KR) 10-2005-0094335

(51) Int. Cl. H01L 29/08; H01L 51/40

(52) U.S. Cl. 257/40; 438/99

(57) ABSTRACT

An organic thin film transistor array panel according to an embodiment of the present invention includes: a substrate; a first signal line disposed on the substrate; a second signal line intersecting the first signal line; a source electrode connected to the first signal line; a drain electrode separated from source electrode; an organic semiconductor member connected to source electrode and drain electrode; a pixel electrode connected to drain electrode; and a passivation layer disposed on pixel electrode and having light-induced alignment.

### CROSS-REFERENCE TO RELATED APPLICATION

This application claims priority to and the benefit of korean patent application no. 10-2,005-0094335 filed in the Korean intellectual property office on Oct. 7, 2005, the contents of which are incorporated herein by reference.

### FIELD OF THE INVENTION

The present invention relates to an organic thin film transistor array panel and a manufacturing method therefor.

### DESCRIPTION OF THE RELATED ART

Generally, a flat panel display such as a liquid crystal display (LCD), an organic light emitting diode (OLED) display, and an electrophoretic display include a pair of electric-field generating electrodes and an electro-optical active layer disposed between the electrodes. The LCD includes a liquid crystal layer as the electro-optical active layer while the OLED display includes an organic light emitting layer as the electro-optical active layer.

A pixel electrode, one of the pair of field generating electrodes is usually coupled with a switching element to receive electrical signals, and the electro-optical active layer converts the electrical signals into optical signals to display images.

The switching element for the flat panel display typically includes a thin film transistor (TFT) having three terminals. Gate lines transmit control signals for controlling the TFTs and data lines transmitting data signals to be supplied to pixel electrodes through the TFTs.

An organic thin film transistor (OTFT) utilizes an organic semiconductor instead of an inorganic semiconductor such as Si. Since organic material can be easily fabricated in forms of a fiber or a film at a low temperature by a solution process, the OTFT is easily applicable to a large flat panel display. However, the OTFT has poor heat resistance and poor chemical resistance as compared with an inorganic TFT and therefor an organic passivation layer is usually required to protecting the OTFT. An LCD also typically includes an alignment layer for aligning liquid crystal molecules. The alignment layer may be made of an organic material that is disposed directly on organic passivation layer to contact organic passivation layer. However, the conventional organic passivation layer adheres poorly to the alignment layer and may adversely affect the alignment of the liquid crystal molecules.

### SUMMARY OF THE INVENTION

An organic thin film transistor array panel according to an embodiment of the present invention includes: a substrate; a first signal line disposed on the substrate; a second signal line intersecting the first signal line; a source electrode connected to the first signal line; a drain electrode separated from source electrode; an organic semiconductor member connected to source electrode and drain electrode; a pixel electrode connected to drain electrode; and a passivation layer disposed on pixel electrode and having light-induced alignment.

Passivation layer may be made of a materila that includes a main chain having at least one of a polyamide acid, polyamide acid ester, polyimide, polymaleimide, polystyrene, a maleimide-styrene copolymer, polyester, polymethylacrylate, polysiloxane, and a copolymer thereof. Passivation layer may further include at least one side chain linked to the main chain and including at least one of an oxetane group, an epoxy group, a (meta)acryloyl group, a (meta)acryloyloxy group, a vinyl group, a vinyloxy group, an azide group, a cinnamoyl group, a chalcone group, and a chloromethyl group.

The one side chain includes at least two side chains that are polymerized under different light wavelengths; a first side chain including a light-polymerizable group that includes at least one of a vinyl group, a cinnamoyl group, and a chalcone group; and a second side chain including a crosslinking group that includes at least one of an oxetane group, an epoxy group, a (meta)acryloyl group, a (meta)acryloyloxy group, a vinyl group, a vinyloxy group, an azide group, and a chloromethyl group.

Passivation layer may have a thickness of from about 1,000Å to about 3,000 Å.

Source electrode, drain electrode, and pixel electrode may be disposed on the same layer.

Organic thin film transistor array panel may further include an insulating layer disposed between the first signal line and source electrode and having a contact hole connecting the first signal line and source electrode.

Organic thin film transistor array panel may further include a stopper disposed on organic semiconductor member, a light blocking member disposed under organic semiconductor member, a bank enclosing organic semiconductor member, or a gate insulator disposed between organic semiconductor member and the second signal line and including an organic material.

A method of manufacturing an organic thin film transistor array panel according to an embodiment of the present invention includes: forming a source electrode and a pixel electrode including a drain electrode on a substrate; forming an organic semiconductor member on source electrode and drain electrode; forming a gate electrode on or under organic semiconductor member; forming a gate insulator between organic semiconductor member and gate electrode; and forming a passivation layer having a light-induced alignment characteristic on organic semiconductor member.

The formation of passivation layer may include: coating an organic layer including a main chain that includes at least one of a polyamide acid, polyamide acid ester, polyimide, polymaleimide, polystyrene, a maleimide-styrene copolymer, polyester, polymethylacrylate, polysiloxane, and a copolymer thereof; and polymerizing organic layer.

The main chain may be linked to a side chain including at least one of an oxetane group, an epoxy group, a (meta)acryloyl group, a (meta)acryloyloxy group, a vinyl group, a vinyloxy group, an azide group, a cinnamoyl group, a chalcone group, and a chloromethyl group.

The polymerization may be performed under heat or light. In particular, the polymerization may include: separately illuminating UV lights having different wavelengths.

The method may further include: forming a stopper between organic semiconductor member and passivation layer.

The formation of source electrode and pixel electrode may also form a data line including source electrode.

The method may further include: forming a data line on the substrate; and forming a first insulating layer on the data line and under source electrode and pixel electrode, wherein the first insulating layer having a first contact hole exposing the data line, and the data line and source electrode are connected to each other through the first contact hole.

The method may further include: forming a second insulating layer on source electrode and pixel electrode, wherein the second insulating layer has a first opening exposing source electrode and drain electrode, and organic semiconductor member is disposed in the opening.

The method may further include: forming a third insulating layer on a gate line including gate electrode and under source electrode and pixel electrode, wherein the third insulating layer having a second opening exposing gate electrode and a second contact hole exposing the first contact hole, gate insulator is disposed in the second opening, and source electrode and the data line are connected to each other through the first and the second contact holes.

The first opening may be smaller than the second opening.

At least one of organic semiconductor member, gate insulator, the first insulating layer, the second insulating layer, the third insulating layer, and passivation layer may be formed by solution process.

Gate insulator may be disposed in the first opening and on organic semiconductor member.

The method may further include: forming a light blocking member disposed opposite organic light emitting member with respect to the first insulating layer.

The first insulating layer may include an inorganic film and an organic film disposed on organic film.

### BRIEF DESCRIPTION OF THE DRAWINGS

The present invention will become more apparent from a reading of the ensuing description together with the drawing, in which:

FIG. 1 is a layout view of an OTFT array panel for an LCD according to an embodiment of the present invention;

FIG. 2 is a sectional view of the OTFT array panel shown in FIG. 1 taken along the line 11-11;

FIGS. 3, 5 and 7 are layout views of the OTFT array panel shown in FIGS. 1 and 2 in intermediate steps of a manufacturing method thereof according to an embodiment of the present invention;

FIG. 4 is a sectional view of the OTFT array panel shown in FIG. 3 taken along the line IV-IV;

FIG. 6 is a sectional view of the OTFT array panel shown in FIG. 5 taken along the line VI-VI;

FIG. 8 is a sectional view of the TFT array panel shown in FIG. 7 taken along the line VIII-VIII;

FIG. 9 is a layout view of an OTFT array panel according to another embodiment of the present invention;

FIG. 10 is a sectional view of the OTFT array panel shown in FIG. 9 taken along the line X-X;

FIGS. 11, 13, 15, 17 and 19 are layout views of the OTFT array panel shown FIGS. 9 and 10 in intermediate steps of a manufacturing method thereof according to an embodiment of the present invention;

FIG. 12 is a sectional view of the OTFT array panel shown in FIG. 11 taken along line XII-XII;

FIG. 14 is a sectional view of the OTFT array panel shown in FIG. 13 taken along line XIV-XIV;

FIG. 16 is a sectional view of the OTFT array panel shown in FIG. 15 taken along line XVI-XVI;

FIG. 18 is a sectional view of the OTFT array panel shown in FIG. 17 taken along line XVIII-XVIII;

FIG. 20 is a sectional view of the OTFT array panel shown in FIG. 19 taken along line XX-XX;

FIG. 21 is a layout view of an OTFT array panel according to another embodiment of the present invention; and

FIG. 22 is a sectional view of the OTFT array panel shown in FIG. 21 taken along line XXII-XXII.

### DETAILED DESCRIPTION OF EMBODIMENTS

The present invention now will be described more fully hereinafter with reference to the accompanying drawings, in which preferred embodiments of the invention are shown. In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

### Embodiment 1

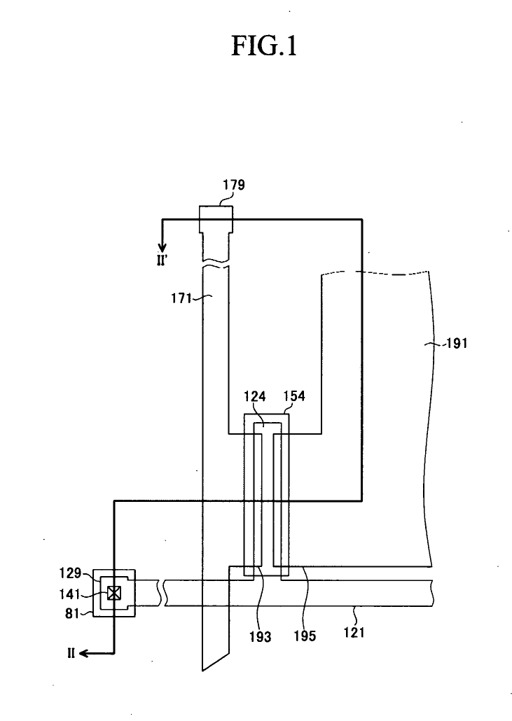

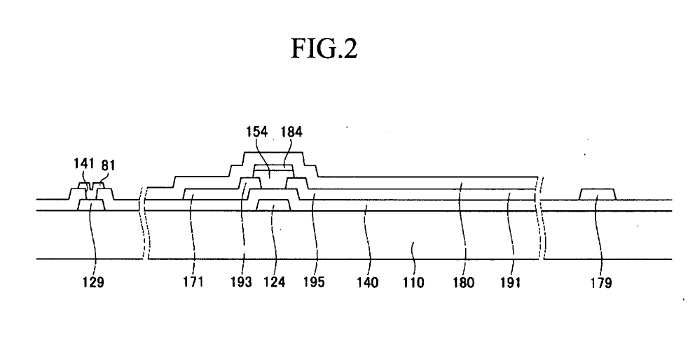

An OTFT array panel for an LCD according to an embodiment of the present invention will be described with reference to FIGS. 1 and 2 in which FIG. 1 is a layout view of an OTFT array panel for an LCD according to an embodiment of the present invention, and FIG. 2 is a sectional view of the OTFT array panel shown in FIG. 1 taken along the line II-II.

A plurality of gate lines 121 are formed on an insulating substrate 110 such as transparent glass, silicone, or plastic.

Gate lines 121 transmit gate signals and extend substantially in a transverse direction. Each of gate lines 121 includes a plurality of gate electrodes 124 protruding upward and an end portion 129 having a large area for contact with another layer or a driving circuit. A gate driving circuit (not shown) for generating gate signals may be mounted on a FPC film (not shown), which may be attached to the substrate 110, directly mounted on the substrate 110, or integrated onto the substrate 110. Gate lines 121 may extend to be connected to a driving circuit that may be integrated on the substrate 110.

Gate lines 121 are preferably made of Al containing metal such as Al and Al alloy, Ag containing metal such as Ag and Ag alloy, Au containing metal such as Au or Au alloy, Cu containing metal such as Cu and Cu alloy, Au containing material such as Au and Au alloy, Mo containing metal such as Mo and Mo alloy, Cr, Ta, Ti, etc. However, they may have a multi-layered structure including two conductive films (not shown) having different physical characteristics. One of the two films is preferably made of low resistivity metal for reducing signal delay or voltage drop. The other film is preferably made of material, which has good physical, chemical, and electrical contact characteristics with other materials such as ITO or indium zinc oxide (IZO). However, gate lines 121 may be made of various metals or conductors.

The lateral sides of gate lines 121 are inclined relative to a surface of the substrate 110, and the inclination angle thereof ranges about 30-80 degrees.

An insulating layer 140 is formed on gate lines 121. Insulating layer 140 may be made of an inorganic insulator or an organic insulator. Examples of the inorganic insulator include silicon nitride (SiNx) and silicon dioxide (SiO₂) that may have a surface treated with octadecyl-trichloro-silane (OTS). Examples of organic insulator include maleimide-styrene, polyvinylphenol (PVP), and modified cyanoethyl pullulan (m-CEP).

It is preferable that insulating layer 140 has good contact characteristics with organic semiconductor and small roughness. Insulating layer 140 has a plurality of contact holes 141 exposing the end portions 129 of gate lines 121.

A plurality of data lines 171, a plurality of pixel electrodes 191, and a plurality of contact assistants 81 are formed on insulating layer 140. Data lines 171 transmit data signals and extend substantially in a longitudinal direction to intersect gate lines 121. Each data line 171 includes a plurality of source electrodes 193 projecting toward gate electrodes 124 and an end portion 179 having a large area for contact with another layer or an external driving circuit. A data driving circuit (not shown) for generating the data signals may be mounted on an FPC film (not shown), which may be attached to the substrate 110, directly mounted on the substrate 110, or integrated onto the substrate 110. Data lines 171 may extend to be connected to a driving circuit that may be integrated on the substrate 110.

Pixel electrodes 191 are separated from data lines 171 and each of pixel electrodes 191 includes a portion 195 (referred to as a drain electrode hereinafter) disposed opposite source electrodes 193 with respect to gate electrodes 124.

Contact assistants 81 are connected to the end portions 129 of gate lines 121 through contact holes 141. Contact assistants 81 protect the end portions 129 and enhance the adhesion between the end portions 129 and external devices.

Data lines 171, pixel electrodes 191, and contact assistants 81 may be made of transparent conductor such as ITO or IZO or reflective conductor such as Ag, Al, Cr, or alloys thereof. The thickness of data lines 171, pixel electrodes 191, and contact assistants 81 may be equal to from about 1,000 Å to about 3000 Å.

Data lines, pixel electrodes 191, and contact assistants 81 have inclined edge profiles, and the inclination angles thereof range about 30-80 degrees.

A plurality of organic semiconductor islands 154 are formed on source electrodes 193, drain electrodes 195, and insulating layer 140. Organic semiconductor islands 154 are disposed on gate electrodes 124 and contact source electrodes 193 and drain electrodes 195.

Organic semiconductor islands 154 may include polymer or oligomer having a structure such as a conjugated system, which can easily move electrons. Organic semiconductor islands 154 may include a low molecular compound or a high molecular compound that is soluble in an aqueous solution or organic solvent. Organic semiconductor islands 154 may be formed from derivatives including a low molecular conjugate compound and a hydrophilic or hydrophobic functional group.

Organic semiconductor islands 154 may include derivatives including a substituent of tetracene or pentacene. Alternatively, organic semiconductor islands 154 may be made of oligothiophene including four to eight thiophenes connected at the positions 2, 5 of thiophene rings.

Organic semiconductor islands 154 may be made of polythienylenevinylene, poly-3-hexylthiophene, polythiophene, phthalocyanine, metallized phthalocyanine, or halogenated derivatives thereof.

Organic semiconductor islands 154 may be made of perylenetetracarboxylic dianhydride (PTCDA), naphthalenetetracarboxylic dianhydride (NTCDA), or their imide derivatives. Organic semiconductor islands 154 may be made of perylene, coronene or derivatives thereof with substituent.

A gate electrode 124, a source electrode 193, and a drain electrode 195 along with an organic semiconductor island 154 form an organic TFT having a channel formed in organic semiconductor island 154 disposed between source electrode 193 and drain electrode 195.

Pixel electrodes 191 receive data voltages from the TFT. Pixel electrodes 191 supplied with data voltages generate electric fields in cooperation with the common electrode (not shown) of an opposing display panel (not shown) supplied with a common voltage. The electric fields determine the orientations of the liquid crystal molecules (not shown) of the liquid crystal layer (not shown) disposed between the two electrodes. A pixel electrode 190 and the common electrode form a capacitor referred to as a “liquid crystal capacitor,” which stores applied voltages after the TFT turns off.

A plurality of stoppers 1 84 are formed on organic semiconductor islands 184. Stoppers 184 protect organic semiconductor islands 154 from external heat, plasma, and chemicals, and may be made of parylene, a fluorine hydrocarbon compound, or poly vinyl alcohol. Stoppers 1 84 may have substantially the same planar shape as organic semiconductor islands 154.

Passivation layer 180 is formed on stoppers 1 84, data lines 171, pixel electrodes 191, and insulating layer 140. Passivation layer 180 protects the TFTs including organic semiconductor islands 154 and functions as an alignment layer that aligns liquid crystal molecules with a direction. Passivation layer 180 does not exist on the end portions 129 of gate lines 121 and on the end portions 179 of data lines 171.

Passivation layer 180 includes a main chain including a polymer or a copolymer thereof. Examples of the polymer or copolymer include a polyamide acid, polyamide acid ester, polyimide, polymaleimide, polystyrene, a maleimide-styrene copolymer, polyester, polymethylacrylate, polysiloxane, and a copolymer thereof, which can be aligned by light.

Passivation layer 180 may further include two kinds of side chains linked to the main chain. A first kind of side chains is a polymerizable group that can form a crosslinkage by heat or light, and a second kind of side chains is an alignable group that can be aligned in a direction by light. However, passivation layer 180 may include only the first kind of side chains when light-induced alignment characteristic of the main chain is sufficient.

Examples of a polymerizable group include an oxetane group, an epoxy group, a (meta)acryloyl group, a (meta)acryloyloxy group, a vinyl group, a vinyloxy group, an azide group, and a chloromethyl group. However, the examples of the polymerizable group are not limited to the above-described groups, and include all groups that can form a crosslinkage by heat or light.

Examples of light-alignable group include a vinyl group, a cinnamoyl group, and a chalcone group, but not limited to these examples.

Chemical formula (I), below, illustrates a structure including a polymerizable group and a light-alignable group:

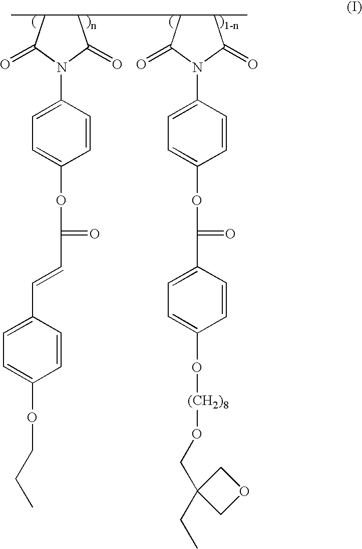

The structure having chemical formula (I) includes a main chain of polymaleimide, a first side chain including a vinyl gourp, and a second side chain including an oxetane group. The polymaleimide and the first side chain exhibit a light-alignable characteristic, and the second side chain form a crosslinkage. In particular, the vinyl group is polymerized to be aligned under a light having a wavelength of about 313 nm, and the oxetane group is polymerized to form a crosslinkage under a light having a wavelength of about 302 nm.

Since a polymer includes both, a portion that can form a crosslinking structure and a portion that can form a light alignment structure, passivation layer 180 performs both protection and alignment.

In addition, since an organic protection film and an alignment film is incorporated into a single film, it can be prevented lifting that may be caused by the difference in physical characteristics between organic protection film and the alignment film, thereby obtaining uniform alignment.

Pixel electrodes 190 overlap gate lines 121 and data lines 171 to increase the aperture ratio.

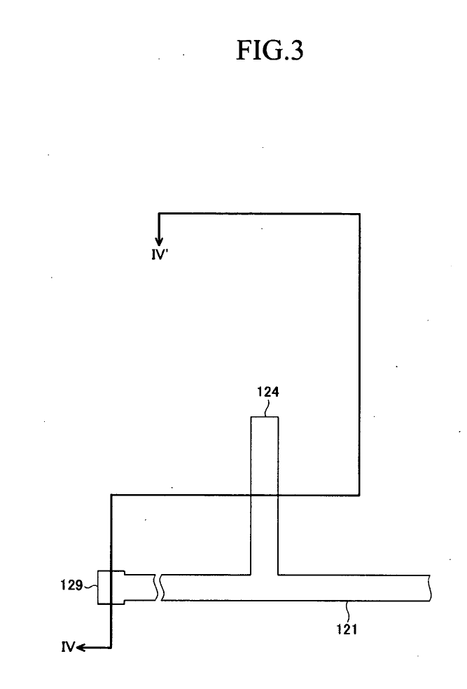

Now, a method of manufacturing the OTFT array panel shown in FIGS. 1 and 2 according to an embodiment of the present invention will be described in detail with reference to FIGS. 3-8 as well as FIGS. 1 and 2.

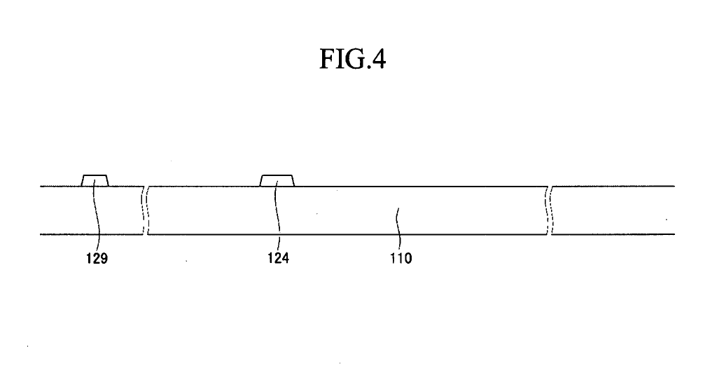

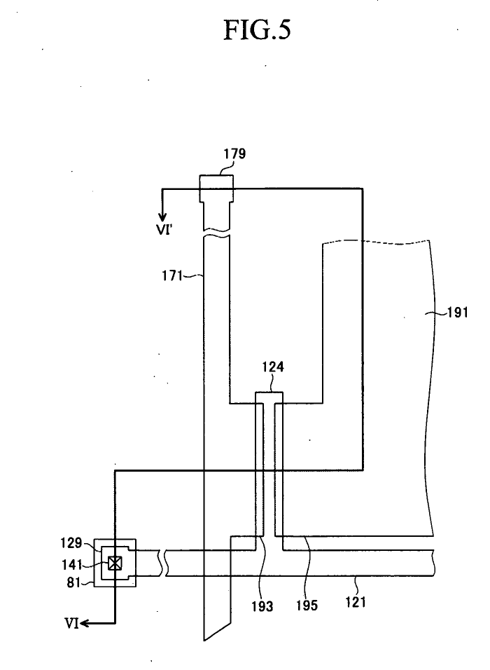

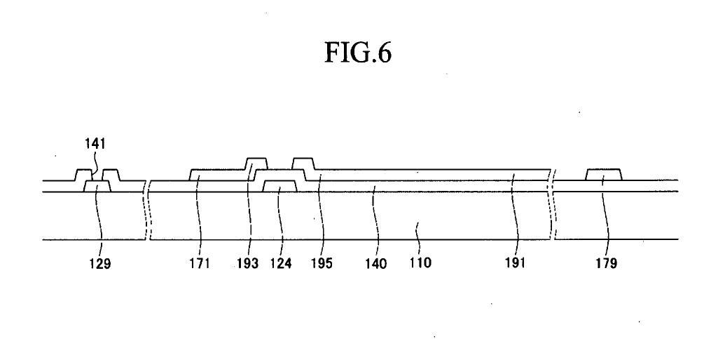

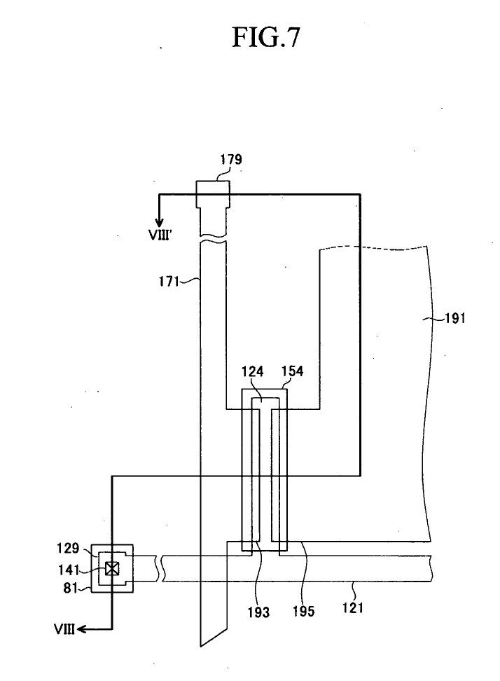

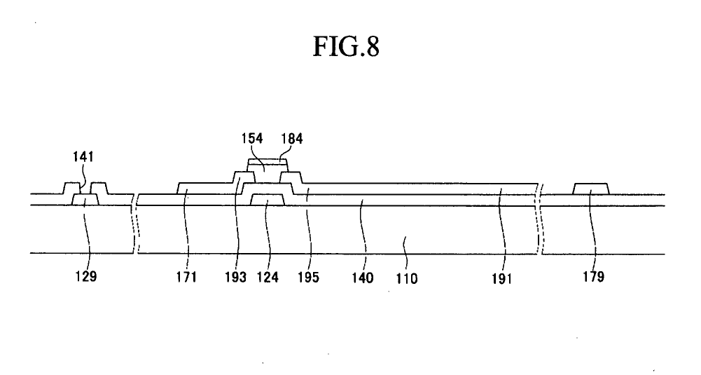

FIGS. 3, 5 and 7 are layout views of the OTFT array panel shown in FIGS. 1 and 2 in intermediate steps of a manufacturing method thereof according to an embodiment of the present invention. FIG. 4 is a sectional view of the OTFT array panel shown in FIG. 3 taken along the line IV-IV, FIG. 6 is a sectional view of the OTFT array panel shown in FIG. 5 taken along the line VI-VI, and FIG. 8 is a sectional view of the TFT array panel shown in FIG. 7 taken along the line VIII-VIII.

Referring to FIGS. 3 and 4, a metal layer is deposited on a substrate 110 by sputtering, etc., and patterned by lithography and etching to form a plurality of gate lines 121 including gate electrodes 124 and end portions 129.

Referring to FIGS. 5 and 6, an inorganic material is deposited by chemical vapor deposition (CVD), etc., or an organic material is spin-coated to form an insulating layer 140 having a plurality of contact holes 141. Contact holes 141 may be formed by lithography and etching for an inorganic material, or only by lithography for a photosensitive organic material.

Subsequently, a metal layer is deposited and patterned by lithography and etching to form a plurality of data lines 171 including source electrodes 193 and end portions 179, a plurality of pixel electrodes 191 including drain electrodes 195, and a plurality of contact assistants 81.

Referring to FIGS. 7 and 8, a plurality of organic semiconductor islands 154 are formed by evaporation, etc.

Successively, an insulating film is deposited by a dry process at a room temperature or a low temperature and patterned by lithography and etching to form a plurality of stoppers 184 that sufficiently cover organic semiconductor islands 154.

Finally, a passivation layer 180 is formed as shown in FIGS. 1 and 2. Passivation layer 180 includes polymaleimide along with a first side chain including a vinyl group and a second side chain including an oxetane group.

An example for synthesizing polymaleimide is given as follows.

First, 10 grams of a maleic anhydride (0.10 mol) and 10.1 grams of amino phenol (0.09 mol) were added into 100 milliliters of toluene 100 and the mixture was agitated for about two hours to form an amic acid. Thereafter, the amic acid was added into 100 milliliters of acetic anhydride and subjected to dehydration by using sodium acetate (CH₃COONa) for about four hours at about 95° C. to obtain 4-acetoxyphenyl maleimide having Chemical Formula (II).

4-acetoxyphenyl maleimide obtained in the above-described step was subjected to radical polymerization by using 2,2′-azobisisobutyronitrile (AIBN) as a polymerization initiator to a maleimide polymer including a predetermined number (n) of polymerized maleimides and having Chemical Formula (III).

Subsequently, 4-acetoxyphenyl maleimide polymer was subjected to a reaction with one liter of a mixture solvent of methanol and acetone and five grams of a p-toluenesulfonic acid for about five hours at a temperature of about 80° C. to a maleimide polymer substituted with a phenol group and having Chemical Formula (IV).

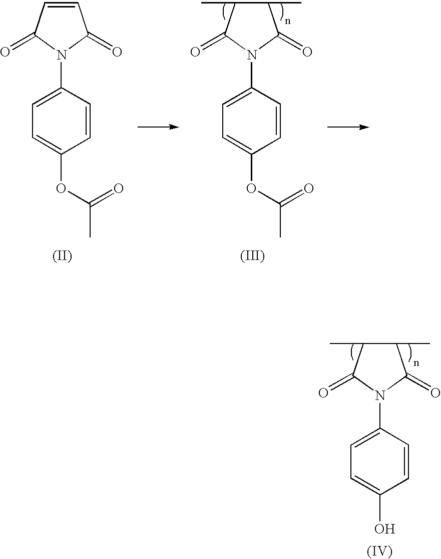

The obtained polymer reacted with a first side chain group and a second side chain group to form a polymer having Chemical Formula (I). The first side chain group includes a vinyl group and has Chemical Formula (V), and the second side chain group includes an oxetane group and has Chemical Formula (VI).

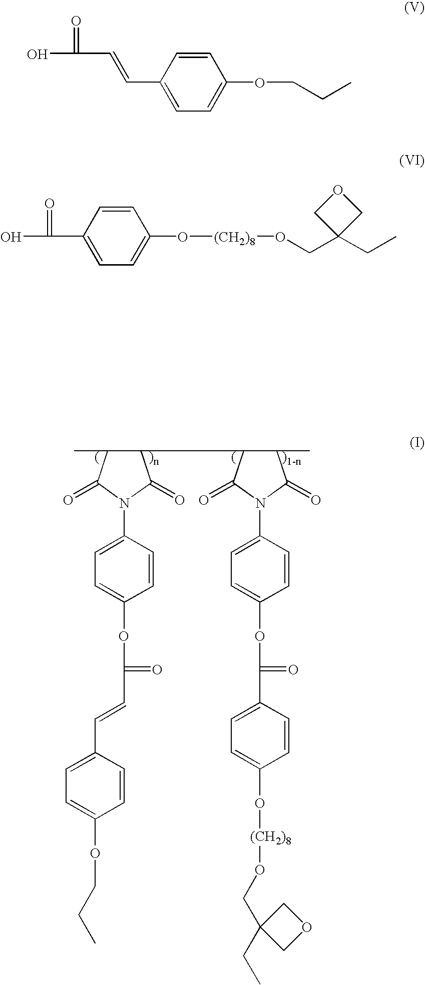

The obtained polymer is spin-coated and exposed to UV lights having a wavelength of about 313 nanometers and of about 302 nanometers. The vinyl group contained in the first side chain group responds to the 313 nm UV light to form a light-alignment structure, and the oxetane group contained in the second side chain group responds to the 302 nm UV light to form a crosslinkage.

Passivation layer 180 may be rubbed.

Various examples of polymers having various main chains and various side chains can be obtained. Some examples may be polymerized by heat at a temperature of from about 100° C. to about 300° C.

### Embodiment 2

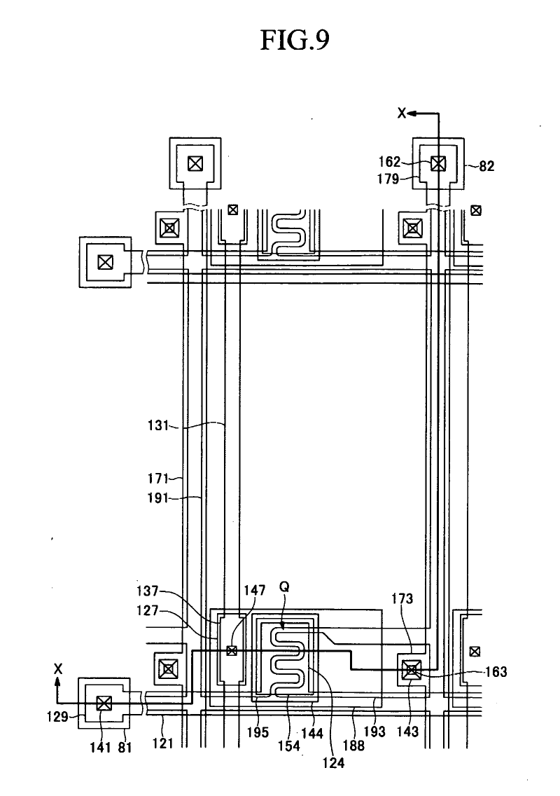

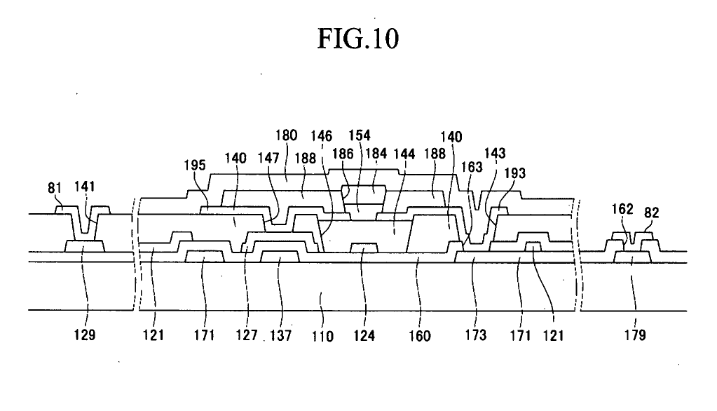

An organic thin film transistor (OTFT) array panel according to another embodiment of the present invention will be described in detail with reference to FIGS. 9 and 10. FIG. 9 is a layout view of an OTFT array panel according to another embodiment of the present invention and FIG. 10 is a sectional view of the OTFT array panel shown in FIG. 9 taken along the line X-X. A plurality of data lines 121 and a plurality of storage electrode lines 1 31 are formed on an insulating substrate 110.

Data lines 171 extend substantially in a longitudinal direction. Each of data lines 171 includes a plurality of projections 173 and an end portion 179 having a large area for contact with another layer or an external driving circuit.

Storage electrode lines 131 are supplied with a predetermined voltage and extend substantially parallel to data lines 171. Each of storage electrode lines 131 is disposed between two adjacent data lines 171 and it is close to the left one of the two adjacent data lines 171. Each of storage electrode lines 131 includes a storage electrode 137 expanding left and right. However, storage electrode lines 131 may have various shapes and arrangements.

Data lines 171 and storage electrode lines 131 have inclined edge profiles, and the inclination angles thereof range about 30-80 degrees.

An interlayer insulating layer 160 is formed on data lines 171 and storage electrode lines 131. Interlayer insulating layer 160 may be made of inorganic insulator or organic insulator. Examples of an inorganic insulator include silicon nitride (SiNx) and silicon oxide (SiOx). The thickness of interlayer insulating layer 160 may be equal to from about 2,000 Å to about 4 microns.

Interlayer insulating layer 160 has a plurality of contact holes 162 exposing the end portions 179 of data lines 171 and a plurality of contact holes 163 exposing the projections 173 of data lines 171.

A plurality of gate lines 121 and a plurality of storage conductors 127 are formed on interlayer insulating layer 160. Gate lines 121 extend substantially in a transverse direction to intersect data lines 171 and storage electrode lines 131. Each of gate lines 121 includes a plurality of gate electrodes 124 projecting upward and an end portion 129 having a large area for contact with another layer or an external driving circuit.

Storage conductors 127 are separated from gate lines 121 and overlap storage electrodes 137. The lateral sides of gate lines 121 and storage electrode lines 131 are inclined relative to a surface of the substrate 110, and the inclination angle thereof ranges about 30-80 degrees.

An insulating layer 140 is formed on gate lines 121 and storage electrode lines 131. Insulating layer 140 may be made of an inorganic insulator or an organic insulator having a relatively low dielectric constant of about 2.5 to about 4.0. An example of organic insulator includes a soluble high molecule compound such as a polyacryl compound, a polystyrene compound, and benzocyclobutane (BCB). Examples of the inorganic insulator include silicon nitride and silicon oxide. The thickness of insulating layer 140 may be from about 5,000 A to about 4 microns.

The low dielectric constant of insulating layer 140 reduces the parasitic capacitance between data lines 171 and gate lines 121 and an overlaying conductive layer.

Insulating layer 140 is not present on the end portions 179 of data lines 171 in order to prevent detachment of interlayer insulating layer 160 and insulating layer 140 near the end portions 179 of data lines 171 due to the poor adhesion between the layers 160 and 140 and to enhance adhesion between the end portions 179 of data lines 171 and an external circuit.

Insulating layer 140 has a plurality of openings 146 exposing gate electrodes 124, a plurality of contact holes 141 exposing the end portions 129 of gate lines 121, and a plurality of contact holes 141 exposing contact holes 163 and the projections 173 of data lines 171, and a plurality of contact holes 147 exposing storage conductors 127.

A plurality of gate insulators 144 are formed in the openings 146 of insulating layer 140. Gate insulators 144 cover gate electrodes 124, and have a thickness of about 1,000 Å to about 10,000 Å. The sidewalls of the openings 146 are higher than gate insulators 144 such that insulating layer 140 serves as banks against gate insulators 144. The openings 146 have a size sufficient to flatten the surfaces of gate insulators 144.

Gate insulators 144 may be made of an inorganic insulator or an organic insulator having a relatively high dielectric constant of about 3.5 to about 10. An example of organic insulator includes a soluble high molecule compound such as a polyimide compound, a polyvinyl alcohol compound, and parylene. An example of the inorganic insulator includes silicon oxide that may have a surface treated with octadecyl-trichloro-silane (OTS). It is preferable that the dielectric constant of gate insulators 144 is higher than that of insulating layer 140.

A plurality of source electrodes 193, a plurality of pixel electrodes 191, and a plurality of contact assistants 81 and 82 are formed on gate insulators 144 and insulating layer 140. They are preferably made of a transparent conductor such as ITO or IZO and have a thickness of about 300 Å to about 800 Å.

Source electrodes 193 are connected to data lines 171 through contact holes 143 and 163 and extend onto gate electrodes 124.

Each of pixel electrodes 191 are connected to a storage conductor 127 through a contact hole 147 and includes a drain electrode 195 disposed on a gate insulator 144 opposite a source electrode 193 with respect to a gate electrode 124. Drain electrodes 195 and source electrodes 193 have serpentine edges that face each other and extend substantially parallel to each other. Pixel electrodes 191 overlap gate lines 121 and data lines 171 to increase the aperture ratio.

Contact assistants 81 and 82 are connected to the end portions 129 of gate lines 121 and the end portions 179 of data lines 171 through contact holes 141 and 162, respectively.

A plurality of insulating banks 188 are formed on source electrodes 193, pixel electrodes 191, gate insulators 144, and insulating layer 140. The banks 188 may be made of photosensitive organic material that can be solution-processed, and the thickness of the banks 188 is equal to from about 5,000 Å to about 4 microns.

The banks 188 have openings 186 disposed on gate electrodes 124 15 and gate insulators 144 and exposing source electrodes 193, the data electrodes 195, and portions of gate insulators 144 disposed therebetween. The openings 186 are smaller than the openings 146 of insulating layer 140 disposed thereunder and containing gate insulators 144. Therefore, the banks 188 fix gate insulators 144 to prevent from lifting and from being infiltrated by chemicals used in manufacturing process.

A plurality of organic semiconductor islands 154 are formed in the openings 186 of the banks 188. Organic semiconductor islands 154 are disposed on gate electrodes 124 and contact source electrodes 193 and drain electrodes 195. The height of organic semiconductor islands 154 is smaller than that of the banks 188 to be completely confined in the banks 188. Since the lateral surfaces of organic semiconductor islands 154 are not exposed, it is prevented that chemicals used in later process steps may not infiltrate organic semiconductor islands 154.

Organic semiconductor islands 154 may include a high molecular compound or a low molecular compound, which is soluble in an aqueous solution or organic solvent, and in this case, organic semiconductor islands 154 can be formed by (inkjet) printing. However, organic semiconductor islands 154 may be formed by other solution processes such as spin coating and slit coating or by chemical or physical deposition and in this case, the banks 188 can be omitted.

The thickness of organic semiconductor islands 154 may be equal to from about 300 Å to 3,000 Å.

A gate electrode 124, a source electrode 193, and a drain electrode 195 along with an organic semiconductor island 154 form an OTFT Q having a channel formed in organic semiconductor island 154 disposed between source electrode 193 and drain electrode 195.

Since a gate insulator 144 disposed between gate electrode 124 and organic semiconductor island 154 has a high dielectric constant, the threshold voltage of the OTFT Q is decreased and the current driven by the OTFT Q is increased, thereby improving the performance of the OTFT Q.

In addition, since insulating layer 140 disposed between gate electrode 124 and source/drain electrode 193/195 has a low dielectric constant, the parasitic capacitance therebetween is decreased.

Pixel electrodes 191 receive data voltages from the OTFT Q and generate electric fields in cooperation with a common electrode (not shown) of an opposing display panel (not shown) supplied with a common voltage, which determine the orientations of liquid crystal molecules (not shown) of a liquid crystal layer (not shown) disposed between the two electrodes. A pixel electrode 191 and the common electrode form a capacitor referred to as a “liquid crystal capacitor,” which stores applied voltages after the OTFT turns off.

A plurality of stoppers 184 are formed on organic semiconductor islands 154. Stoppers 184 may be made of a fluorine hydrocarbon compound or a polyvinyl alcohol compound. Stoppers 184 protect organic semiconductor islands 154 from external heat, plasma, or chemicals.

A passivation layer 180 is formed on stoppers 184, the OTFTs Q, and the banks 188. Passivation layer 180 protects the OTFTs Q including organic semiconductor islands 154 and aligns liquid crystal molecules like passivation layer 180 shown in FIGS. 1 and 2.

Many of the features of the OTFT array panel shown in FIGS. 1 and 2 may be applicable to the OTFT array panel shown in FIGS. 9 and 10.

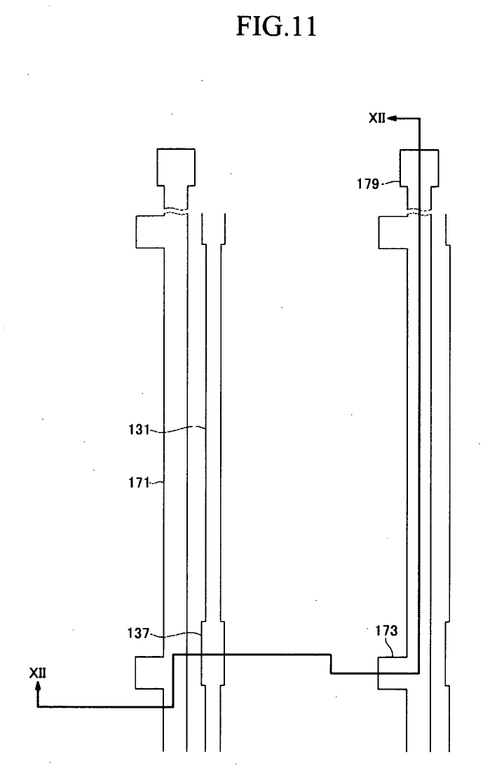

Now, a method of manufacturing the OTFT array panel shown in FIGS. 9 and 10 according to an embodiment of the present invention will be described in detail with reference to FIGS. 11-20 as well as FIGS. 9 and 10.

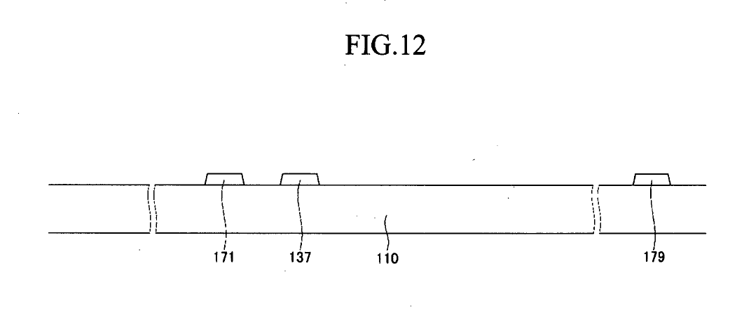

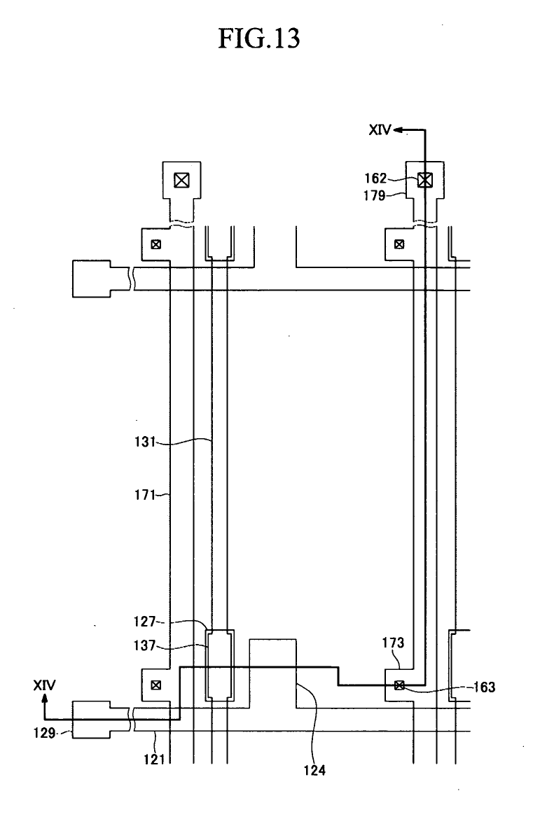

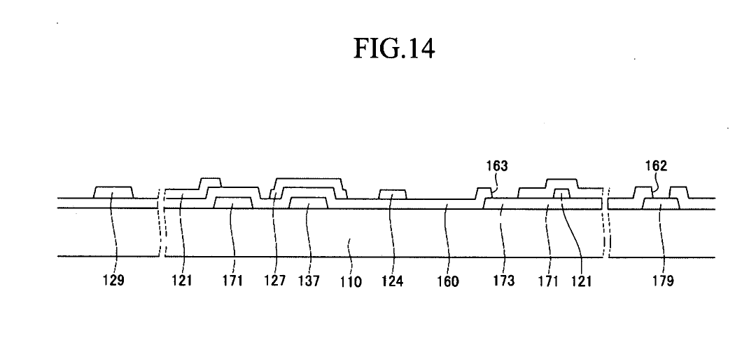

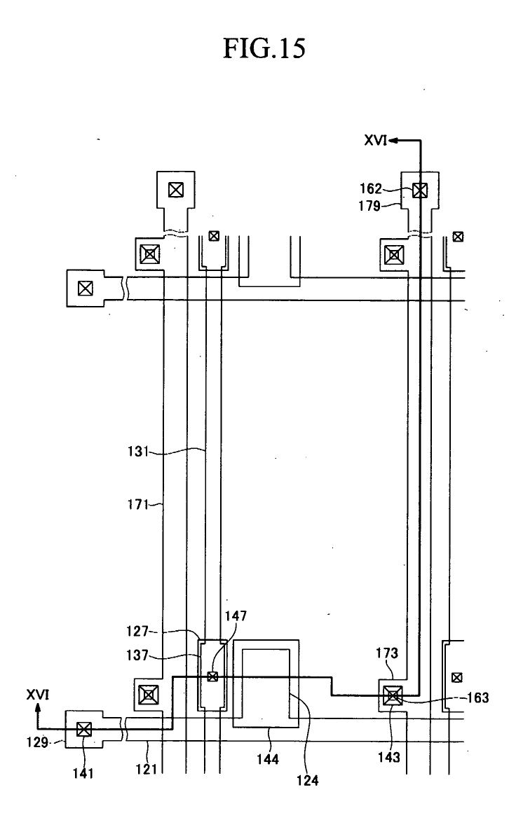

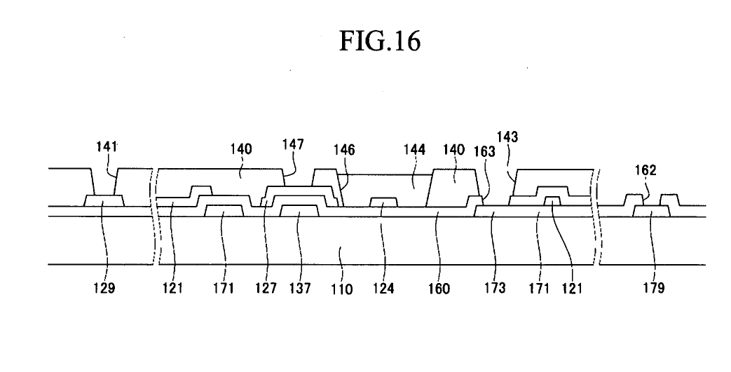

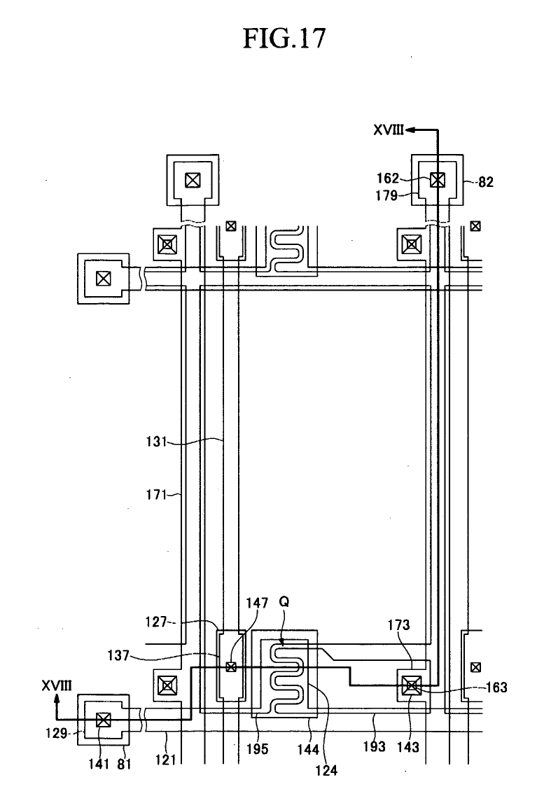

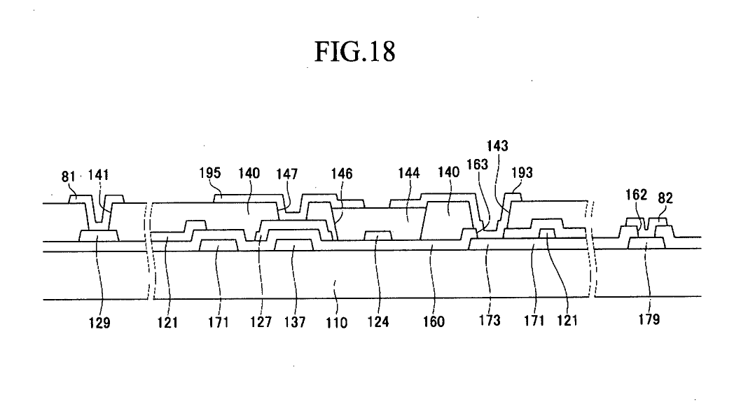

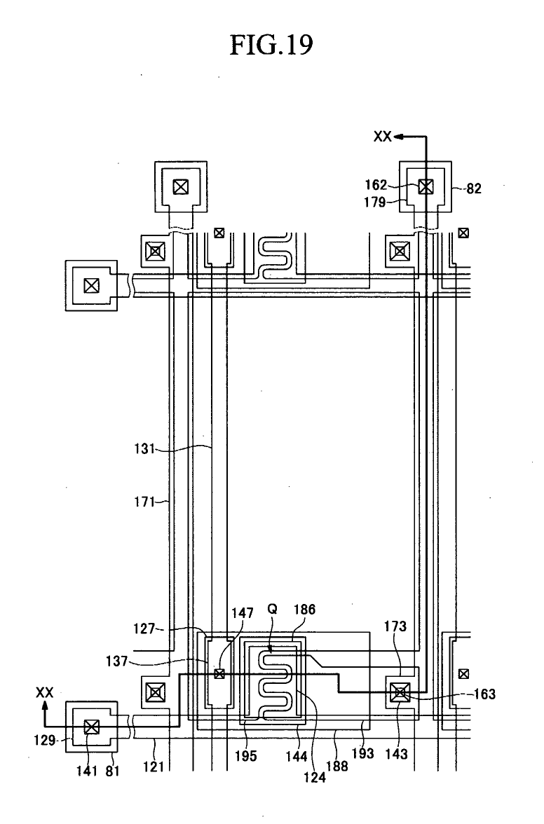

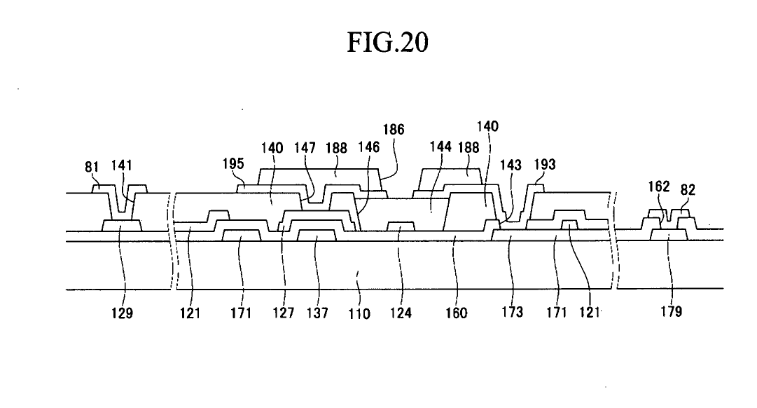

FIGS. 11, 13, 15, 17 and 19 are layout views of the OTFT array panel shown FIGS. 9 and 10 in intermediate steps of a manufacturing method thereof according to an embodiment of the present invention, FIG. 12 is a sectional view of the OTFT array panel shown in FIG. 11 taken along line XII-XII, FIG. 14 is a sectional view of the OTFT array panel shown in FIG. 13 taken along line XIV-XIV, FIG. 16 is a sectional view of the OTFT array panel shown in FIG. 15 taken along line XVI-XVI, FIG. 18 is a sectional view of the OTFT array panel shown in FIG. 17 taken along line XVIII-XVIII, and FIG. 20 is a sectional view of the OTFT array panel shown in FIG. 19 taken along line XX-XX.

Referring to FIGS. 11 and 12, a metal layer is deposited on a substrate 110 by using sputtering, etc., and patterned by lithography and etch to form a plurality of data lines 171 including projections 173 and end portions 179 and a plurality of storage electrode lines 131 including storage electrodes 137.

Referring to FIGS. 13 and 14, an interlayer insulating layer 160 including a plurality of contact holes 162 and 163 is formed by deposition and patterning. The deposition of interlayer insulating layer 160 is performed by CVD of an inorganic material or by spin coating of organic material. The patterning of interlayer insulating layer 160 is performed by lithography and etching of an inorganic material, or only by lithography of a photosensitive organic material

Subsequently, a metal layer is deposited and patterned by lithography and etching to form a plurality of gate lines 121 including gate electrodes 124 and end portions 129 and a plurality of storage capacitors 127.

Referring to FIGS. 15 and 16, a photosensitive organic insulating film is spin-coated and patterned to form an insulating layer 140 having a plurality of openings 146 and a plurality of contact holes 141, 143 and 147. At this time, portions of the photosensitive organic insulating film near the end portions 179 of data lines 171 are fully removed.

Successively, a plurality of gate insulators 144 are formed in the openings 146 of insulating layer 140 by inkjet printing, etc. The inkjet printing includes drop and dry of solution. However, gate insulators 144 may be formed by other solution processes such as spin coating and slit coating.

Referring to FIGS. 17 and 18, an amorphous ITO layer is deposited by sputtering, etc., and patterned by lithography and etch to form a plurality of source electrodes 193, a plurality of pixel electrodes 190 including drain electrodes 195, and a plurality of contact assistants 81 and 82.

The sputtering of the amorphous ITO layer may be performed at a low temperature of from about 25° C. to about 130° C., preferably at a room temperature. The etching of the amorphous ITO layer may be wet etch with a weak alkaline etchant. The low temperature and the weak alkaline etchant may reduce the damage on gate insulators 144 and insulating layer 140 caused by heat and chemicals.

Referring to FIGS. 19 and 20, a photosensitive insulating layer is coated and subjected to light exposure and development to form a plurality of banks 188 having a plurality of openings 186.

Referring to FIGS. 9 and 10, a plurality of organic semiconductor islands 154 and a plurality of stoppers 184 are sequentially formed in the openings 186 by inkjet printing, etc.

Finally, a passivation layer 180 is formed and rubbed.

### Embodiment 3

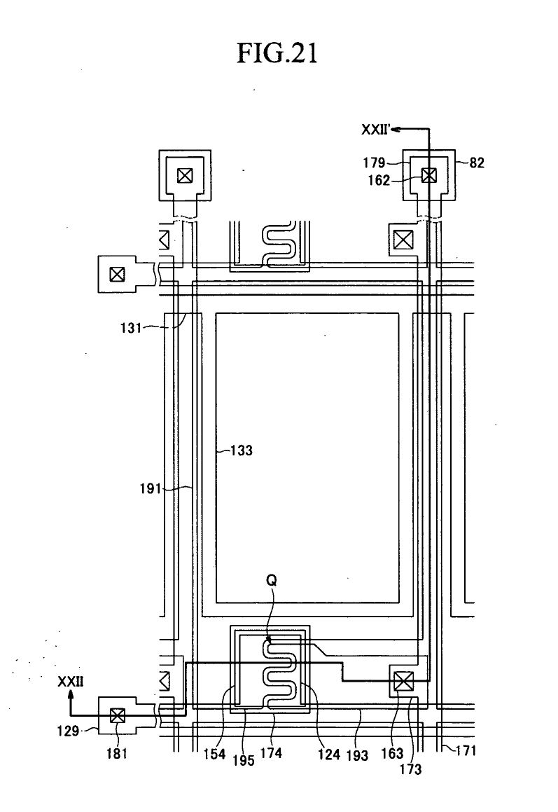

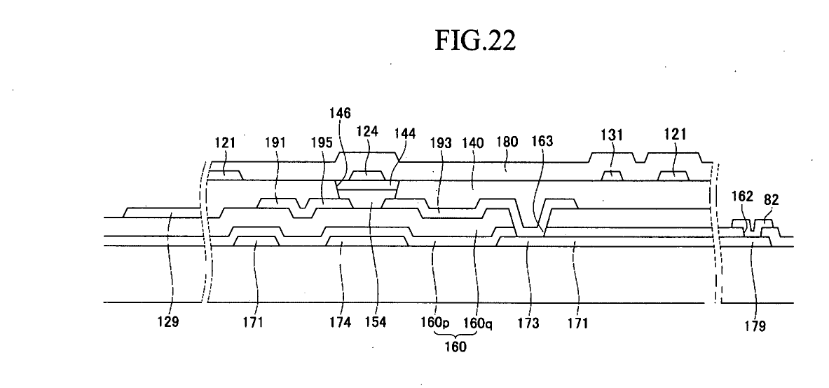

An OTFT array panel for a liquid crystal display according to another embodiment of the present invention will be described in detail with reference to FIGS. 21 and 22. FIG. 21 is a layout view of an OTFT array panel according to another embodiment of the present invention, and FIG. 22 is a sectional view of the OTFT array panel shown in FIG. 21 taken along line XXII-XXII.

A plurality of data lines 121 and a plurality of light blocking members 174 are formed on a substrate 110. Each of data lines 171 extend substantially in a longitudinal direction and includes a plurality of projections 173 projecting left and right and an end portion 179 having a large area for contact with another layer or an external driving circuit.

Light blocking members 174 are spaced apart from data lines 171. Data lines 171 and light blocking members 174 have inclined edge profiles, and the inclination angles thereof range about 30-80 degrees.

An interlayer insulating layer 160 including a lower insulating film 160p and an upper insulating film 160p and 160q is formed on data lines 171 and light blocking members 174. The lower insulating film 160p may be made of inorganic insulator such as silicon nitride (SiNx) and silicon oxide (SiOx). The upper insulating film 160q may be made of organic insulator such as polyacryl, polyimide, and benzocyclobutene (BCB; C₁₀H₈) having good durability. One of the lower and the upper insulating films 160p and 160q may be omitted.

Interlayer insulating layer 160 has a plurality of contact holes 162 exposing the end portions 179 of data lines 171 and a plurality of contact holes 163 exposing the projections 173 of data lines 171.

A plurality of source electrodes 193, a plurality of pixel electrodes 191, and a plurality of contact assistants 82 are formed on interlayer insulating layer 160. They may be made of a transparent conductor such as ITO and IZO or a reflective conductor.

Source electrodes 193 are connected to the projections 173 of data lines 171 through contact holes 163.

Each pixel electrode 191 includes a portion 195 disposed opposite a source electrode 193 with respect to a gate electrode 124, which is referred to as a drain electrode hereinafter. Drain electrodes 195 and source electrodes 193 have serpentine edges that face each other and extend substantially parallel to each other. Pixel electrodes 191 overlap gate lines 121 and data lines 171 to increase the aperture ratio.

Contact assistants 82 are connected to the end portions 179 of data lines 171 through contact holes 162. Contact assistants 82 protect the end portions 179 and enhance the adhesion between the end portions 179 and external devices.

An insulating layer 140 is formed on source electrodes 193 and pixel electrodes 191. Insulating layer 140 has a plurality of openings 146 exposing portions of source electrodes 193 and drain electrodes 195, including opposing serpentine edges of source electrodes 193 and drain electrodes 195. Insulating layer 140 may be made of photosensitive organic material such as poly acryl or polyimide, and may have a thickness of about 1-3 microns.

A plurality of organic semiconductor islands 154 are formed in the openings 146 of insulating layer 140. Organic semiconductor islands 154 are disposed on gate electrodes 124 and light blocking members 174 and contact source electrodes 193 and drain electrodes 195.

Organic semiconductor islands 154 may include a soluble organic compound such as polythienylenevinylene, oligothiophene, poly 3-hexylthiophene, and soluble pentacene. Organic semiconductor islands 154 can be formed by inkjet printing. The thickness of organic semiconductor islands 154 is equal to from about 500 to about 2,000 Å.

A plurality of gate insulators 144 are formed on organic semiconductor islands 154 and also confined in the openings 146 along with organic semiconductor islands 154. Gate insulators 144 may be made of organic insulator such as a fluorine hydrocarbon compound, poly vinyl alcohol, or polyimide, and can be formed by inkjet printing.

Since organic semiconductor islands 154 is fully enclosed by insulating layer 140 and gate insulators 144, organic semiconductor islands 154 are protected from being damaged in manufacturing process.

Light blocking members 174, which are disposed under organic semiconductor islands 154, block incident light to prevent current light induced by light.

A plurality of gate lines 121, and a plurality of storage electrode lines 131 are formed on insulating layer 140 and gate insulators 144.

Gate lines 121 extend substantially in a transverse direction to intersect data lines 171. Each of gate lines 121 includes a plurality of gate electrodes 124 projecting upward and an end portion 129 having a large area for contact with another layer or an external driving circuit.

Each of storage electrode lines 131 is disposed between two adjacent gate lines 121 and includes a stem and a plurality of storage electrodes 133. The stem extends substantially parallel to gate lines 121 and is close to upper one of the two adjacent gate lines 121. Each of storage electrodes 133 is branched from the stem and forms a rectangle along with the stem to define a closed area.

The lateral sides of gate lines 121 and storage electrode lines 131 are inclined relative to a surface of the substrate 110, and the inclination angle thereof ranges about 30-80 degrees.

A gate electrode 124, a source electrode 193, and a drain electrode 195 along with an organic semiconductor island 154 form an OTFT Q having a channel formed in organic semiconductor island 154 disposed between source electrode 193 and drain electrode 195.

A passivation layer 180 is formed on gate lines 121 and storage electrode lines 131. Passivation layer 180 has an aligning characteristic like passivation layer 180 shown in FIGS. 1 and 2.

Many of the features of the OTFT array panel shown in FIGS. 1-20 may be applicable to the OTFT array panel shown in FIGS. 21 and 22. Although preferred embodiments of the present invention have been described in detail hereinabove, it should be clearly understood that many variations and/or modifications of the basic inventive concepts herein taught will occur to those skilled in the present art and may be made without, however, departing from the spirit and scope of the present invention.

What is claimed is:

1. An organic thin film transistor array panel comprising:
a substrate;
a first signal line disposed on the substrate;
a second signal line intersecting the first signal line;
a source electrode connected to the first signal line;
a drain electrode separated from the source electrode;
an organic semiconductor member connected to the source electrode and the drain electrode;
a pixel electrode connected to the drain electrode; and
a passivation layer disposed on the pixel electrode and having light-induced alignment.

2. The organic thin film transistor array panel of claim 1, wherein the passivation layer comprises a main chain comprising at least one of a polyamide acid, polyamide acid ester, polyimide, polymaleimide, polystyrene, a maleimide-styrene copolymer, polyester, polymethylacrylate, polysiloxane, and a copolymer thereof.

3. The organic thin film transistor array panel of claim 2, wherein the passivation layer further comprises at least one side chain linked to the main chain and comprising at least one of an oxetane group, an epoxy group, a (meta)acryloyl group, a (meta)acryloyloxy group, a vinyl group, a vinyloxy group, an azide group, a cinnamoyl group, a chalcone group, and a chloromethyl group.

4. The organic thin film transistor array panel of claim 3, wherein the at least one side chain comprises at least two side chains that are polymerized under different light wavelengths.

5. The organic thin film transistor array panel of claim 4, wherein the at least one side chain comprises:
a first side chain comprising a light-polymerizable group that comprises at least one of a vinyl group, a cinnamoyl group, and a chalcone group; and
a second side chain comprising a crosslinking group that comprises at least one of an oxetane group, an epoxy group, a (meta)acryloyl group, a (meta)acryloyloxy group, a vinyl group, a vinyloxy group, an azide group, and a chloromethyl group.

6. The organic thin film transistor array panel of claim 1, wherein the passivation layer has a thickness of from about 1,000 Å to about 3,000 Å.

7. The organic thin film transistor array panel of claim 1, wherein the source electrode, the drain electrode, and the pixel electrode are disposed on the same layer.

8. The organic thin film transistor array panel of claim 1, further comprising an insulating layer disposed between the first signal line and the source electrode and having a contact hole connecting the first signal line and the source electrode.

9. The organic thin film transistor array panel of claim 1, further comprising a stopper disposed on the organic semiconductor member.

10. The organic thin film transistor array panel of claim 1, further comprising a light blocking member disposed under the organic semiconductor member.

11. The organic thin film transistor array panel of claim 1, further comprising a bank enclosing the organic semiconductor member.

12. The organic thin film transistor array panel of claim 1, further comprising a gate insulator disposed between the organic semiconductor member and the second signal line and comprising an organic material.

13. A method of manufacturing an organic thin film transistor array panel, the method comprising:
forming a source electrode and a pixel electrode including a drain electrode on a substrate;
forming an organic semiconductor member on the source electrode and the drain electrode;
forming a gate electrode on or under the organic semiconductor member;
forming a gate insulator between the organic semiconductor member and the gate electrode; and
forming a passivation layer having a light-induced alignment characteristic on the organic semiconductor member.

14. The organic thin film transistor array panel of claim 13, wherein the formation of the passivation layer comprises:
coating an organic layer comprising a main chain that comprises at least one of a polyamide acid, polyamide acid ester, polyimide, polymaleimide, polystyrene, a maleimide-styrene copolymer, polyester, polymethylacrylate, polysiloxane, and a copolymer thereof; and
polymerizing the organic layer.

15. The method of claim 14, wherein the main chain is linked to a side chain comprising at least one of an oxetane group, an epoxy group, a (meta)acryloyl group, a (meta)acryloyloxy group, a vinyl group, a vinyloxy group, an azide group, a cinnamoyl group, a chalcone group, and a chloromethyl group.

16. The method of claim 14, wherein the polymerization is performed under heat or light.

17. The method of claim 16, wherein the polymerization comprises:
separately illuminating UV lights having different wavelengths.

18. The method of claim 13, further comprising:
forming a stopper between the organic semiconductor member and the passivation layer.

19. The method of claim 13, wherein the formation of the source electrode and the pixel electrode also forms a data line including the source electrode.

20. The method of claim 13, further comprising:
forming a data line on the substrate; and
forming a first insulating layer on the data line and under the source electrode and the pixel electrode,
wherein the first insulating layer having a first contact hole exposing the data line, and the data line and the source electrode are connected to each other through the first contact hole.

21. The method of claim 20, further comprising:
forming a second insulating layer on the source electrode and the pixel electrode,
wherein the second insulating layer has a first opening exposing the source electrode and the drain electrode, and the organic semiconductor member is disposed in the opening.

22. The method of claim 21, further comprising:
forming a third insulating layer on a gate line including the gate electrode and under the source electrode and the pixel electrode,
wherein the third insulating layer having a second opening exposing the gate electrode and a second contact hole exposing the first contact hole, the gate insulator is disposed in the second opening, and the source electrode and the data line are connected to each other through the first and the second contact holes.

23. The method of claim 22, wherein the first opening is smaller than the second opening.

24. The method of claim 22, wherein at least one of the organic semiconductor member, the gate insulator, the first insulating layer, the second insulating layer, the third insulating layer, and the passivation layer is formed by solution process.

25. The method of claim 21, wherein the gate insulator is disposed in the first opening and on the organic semiconductor member.

26. The method of claim 25, further comprising:
forming a light blocking member disposed opposite the organic light emitting member with respect to the first insulating layer.

27. The method of claim 25, wherein the first insulating layer comprises an inorganic film and an organic film disposed on the organic film.
